(19) United States
(12) Patent Application Publication
(10) Pub. No.: US 2021/0390890 A1
(43) Pub. Date: Dec. 16, 2021

(54) DISPLAY DEVICE AND TEMPERATURE PROTECTION METHOD THEREOF

(71) Applicant: Coretronic Corporation, Hsin-Chu (TW)

(72) Inventors: Nan-Jiun Yin, Hsin-Chu (TW); Shih-Hung Hsu, Hsin-Chu (TW)

(73) Assignee: Coretronic Corporation, Hsin-Chu (TW)

(21) Appl. No.: 17/342,554

(22) Filed: Jun. 9, 2021

(30) Foreign Application Priority Data
Jun. 12, 2020 (CN) 202010533378.3

(51) Int. Cl. G09G 3/00; G09G 5/10; G09G 3/32; G06F 1/20

(52) U.S. Cl. CPC G09G 3/006; G09G 5/10; G09G 3/32; G09G 2320/0626; G09G 2330/045; G09G 2320/041; G06F 1/206

(57) ABSTRACT

A display device and a temperature protection method thereof are provided. The display device includes a temperature sensing circuit and a control circuit. The temperature sensing circuit is disposed in a casing of the display device. The temperature sensing circuit changes a resistance value according to a temperature of the display device to generate a voltage value. The control circuit determines whether to perform at least one cooling operation according to the voltage value of the temperature sensing circuit, so as to reduce the temperature of the display device and prevent the temperature of the display device from being too high.

### CROSS-REFERENCE TO RELATED APPLICATION

This application claims the priority benefit of China application serial no. 202010533378.3, filed on Jun. 12, 2020. The entirety of the above-mentioned patent application is hereby incorporated by reference herein and made a part of this specification.

### BACKGROUND

### Technical Field

The disclosure relates to an electronic device, and particularly relates to a display device and a temperature protection method thereof.

### Description of Related Art

The operating temperature of the display device is limited. How to reduce the temperature of the display device is one of the important technical issues of the display device. Since the fan generates noise, the display device is not equipped with a fan to dissipate heat. In general, the display device adopts the manner of natural convection to dissipate heat. One or more heat dissipation holes are disposed at the top of the casing of the display device, and one or more heat dissipation holes are also disposed at the bottom of the casing of the display device. Cold air enters the inside of the display device from the heat dissipation hole at the bottom, and hot air inside the display device flows out from the heat dissipation hole at the top, so as to dissipate heat.

Environmental factors or other factors may affect the heat dissipation efficiency of the display device. For example, the heat dissipation efficiency of the display device may be affected due to dust accumulation in the heat dissipation hole. Alternatively, the heat dissipation hole may have insufficient heat dissipation space (which causes the air flow rate to be slower, and even failed discharged of hot air) due to the display device being too close to the wall (or even being embedded in the wall), thereby affecting the heat dissipation efficiency. The poor heat dissipation efficiency of the display device causes the temperature of the display device to rise. The temperature of the display device being too high may cause the system of the display device to be abnormal. For example, once the temperature of the light emitting diode (LED) of the display device is too high, the LED element will be burned. In addition, excessively high temperature will melt the wire rubber inside the display device, causing short circuit and fire. Therefore, the temperature monitoring and management of the display device is one of the very important technical issues.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY

The disclosure provides a display device and a temperature protection method thereof to prevent the temperature of a display device from being too high.

In an embodiment of the disclosure, the display device includes a temperature sensing circuit and a control circuit. The temperature sensing circuit is disposed in the casing of the display device. The temperature sensing circuit is configured to change the resistance value according to the temperature of the display device, so as to generate the voltage value. The control circuit is configured to determine whether to perform at least one cooling operation according to the voltage value of the temperature sensing circuit, so as to reduce the temperature of the display device.

In an embodiment of the disclosure, the temperature protection method includes the following steps. The resistance value is changed according to the temperature of the display device through the temperature sensing circuit to generate the voltage value. Whether to perform at least one cooling operation is determined according to the voltage value of the temperature sensing circuit through the control circuit, so as to reduce the temperature of the display device.

Based on the above, the display device and the temperature protection method according to the embodiments of the disclosure configure the temperature sensing circuit in the casing of the display device. The control circuit may determine whether to perform at least one cooling operation according to the operation of the temperature sensing circuit. The cooling operation may reduce the temperature of the display device to prevent the temperature of the display device from being too high.

Other objectives, features and advantages of the disclosure will be further understood from the further technological features disclosed by the embodiments of the disclosure wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a circuit block of a display device according to an embodiment of the disclosure.

FIG. 2 is a schematic flowchart of a temperature protection method of a display device according to an embodiment of the disclosure.

FIG. 3 is a schematic diagram illustrating a block circuit of a temperature sensing circuit shown in FIG. 1 according to an embodiment of the disclosure.

FIG. 4 is a schematic diagram illustrating the block circuit of the temperature sensing circuit shown in FIG. 1 according to another embodiment of the disclosure.

FIG. 5 is a schematic flowchart of a cooling operation (cooling countermeasure) according to an embodiment of the disclosure.

FIG. 6 is a schematic diagram illustrating a display element being divided into multiple display element rows according to an embodiment of the disclosure.

FIG. 7 is a schematic flowchart of a cooling operation (cooling countermeasure) according to another embodiment of the disclosure.

FIG. 8 is a schematic flowchart of a cooling operation (cooling countermeasure) according to yet another embodiment of the disclosure.

FIG. 9 is a schematic diagram illustrating a display element being divided into multiple display element columns according to an embodiment of the disclosure.

FIG. 10 is a schematic flowchart of a cooling operation (cooling countermeasure) according to yet another embodiment of the disclosure.

FIG. 11 is a schematic flowchart of a cooling operation (cooling countermeasure) according to another embodiment of the disclosure.

FIG. 12 is a schematic diagram illustrating the block circuit of the temperature sensing circuit shown in FIG. 1 according to yet another embodiment of the disclosure.

FIG. 13 is a schematic diagram illustrating the block circuit of the temperature sensing circuit shown in FIG. 1 according to another embodiment of the disclosure.

### DETAILED DESCRIPTION OF DISCLOSED EMBODIMENTS

It is to be understood that other embodiment may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings.

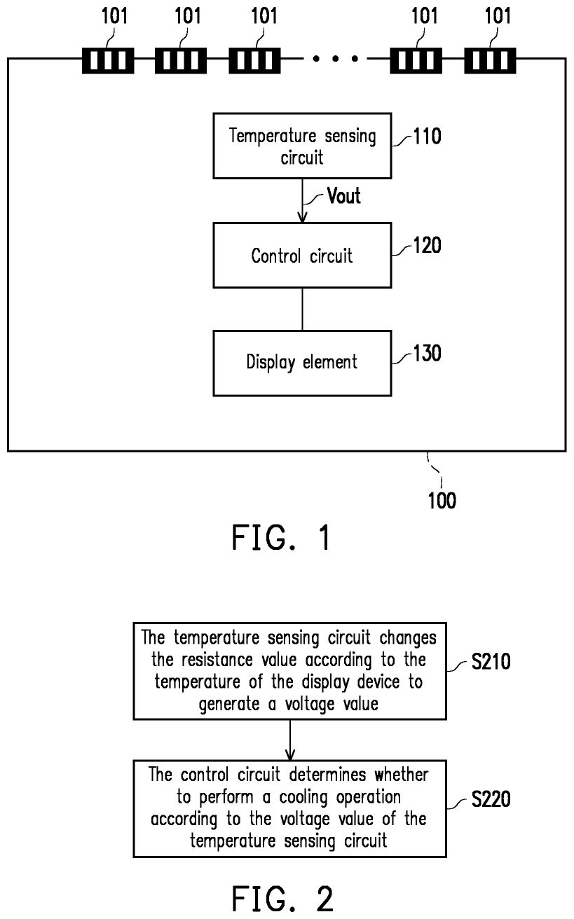

FIG. 1 is a schematic diagram of a circuit block of a display device according to an embodiment of the disclosure. The display device shown in FIG. 1 includes a temperature sensing circuit 110, a control circuit 120, and a display element 130. According to design requirements, the display element 130 may include, for example, a light tube, a light emitting diode (LED), and/or other light emitting elements. In the embodiment, the display device may be an LED display, which has an LED array.

The temperature sensing circuit 110 is disposed in a casing 100 of the display device. According to design requirements, the casing 100 of the display device may be configured with one or more heat dissipation holes 101. The number and position of the heat dissipation hole 101 may be determined according to design requirements. For example, in the embodiment, one or more air inlets are disposed at the bottom surface of the casing 100 of the display device, and one or more heat dissipation holes 101 (air outlets) are also disposed at the top surface of the casing 100 of the display device, so that external air flows through the display element 130, the control circuit 120, and the temperature sensing circuit 110 from one or more air inlets disposed at the bottom surface of the casing 100 of the display device, and flows out from one or more heat dissipation holes 101 disposed at the top surface of the casing 100 of the display device. In other embodiments, the heat dissipation hole 101 is configured at the side surface and/or the back surface of the casing 100 of the display device. In addition, the bottom surface of the casing 100 of the display device is closer to the ground than the top surface of the casing 100 of the display device.

The position of the temperature sensing circuit 110 may be determined according to design requirements. For example, in some embodiments, the temperature sensing circuit 110 may be disposed around at least one heat dissipation hole 101 of the casing 100 of the display device. In some other embodiments, the temperature sensing circuit 110 may be disposed around the display element 130 or in the display element 130. In some other embodiments, the temperature sensing circuit 110 may be disposed around the control circuit 120.

FIG. 2 is a schematic flowchart of a temperature protection method of a display device according to an embodiment of the disclosure. Please refer to FIG. 1 and FIG. 2. In Step S210, the temperature sensing circuit 110 may change the resistance value according to the temperature of the display device to generate a voltage value Vout. The control circuit 120 is coupled to the temperature sensing circuit 110 to receive the voltage value Vout. In Step S220, the control circuit 120 may determine whether to perform at least one cooling operation (cooling countermeasure) according to the voltage value Vout of the temperature sensing circuit 110, so as to reduce the temperature of the display device. According to design requirements, the cooling operation may include “shutting down the display element 130 of the display device”, “reducing the brightness of the display element 130”, “shutting down the corresponding portion of the screen displayed by the display device”, shutting down, and/or other cooling operations. During the cooling operation, according to design requirements, the control circuit 120 may also determine whether to display an alert signal on the screen of the display device in the manner of on-screen display (OSD) according to the voltage value Vout of the temperature sensing circuit 110.

According to design requirements, the temperature sensing circuit 110 may include multiple temperature switches. The temperature switches may be selectively turned on or turned off according to the temperature of the display device. When the temperature reaches the limit temperature (the limit temperature may be selected or pre-set), the temperature switch may be triggered. After the temperature is lower than the limit temperature, the temperature switch may be restored. In conventional technology, the temperature switches may be divided into two types, one is normal close and the other is normal open. When the temperature reaches the limit temperature (the limit temperature may be selected or pre-set), the normal close temperature switch is turned off, but the normal open temperature switch is turned on. After the temperature is lower than the limit temperature, the normal close temperature switch restores to be turned on, but the normal open temperature switch restores to be turned off. The temperature switches of the temperature sensing circuit 110 may be selectively turned on or turned off according to the temperature of the display device to change the total resistance value of the temperature sensing circuit 110.

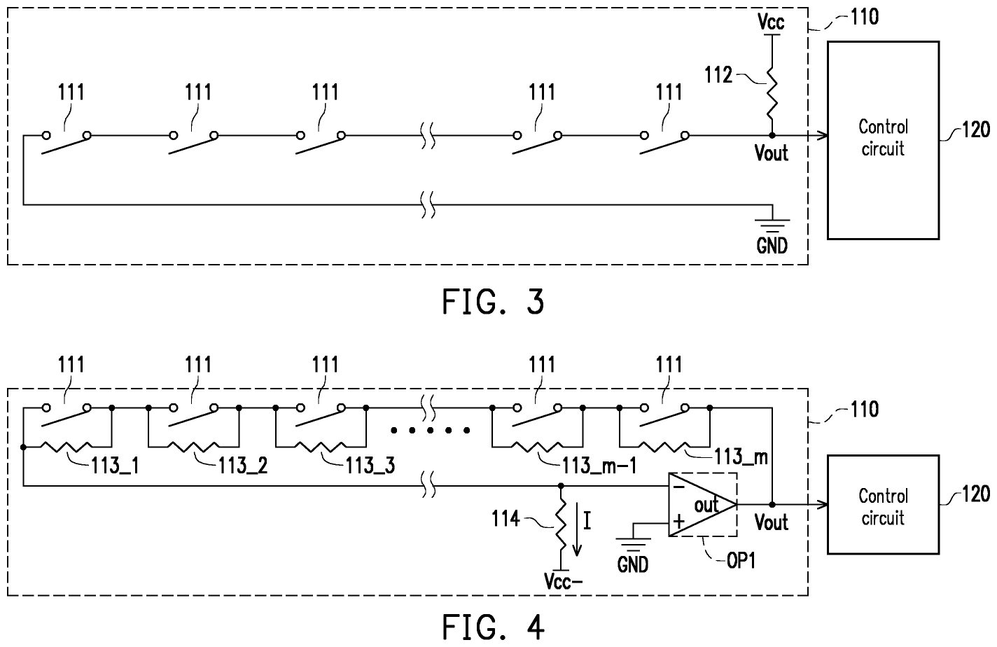

FIG. 3 is a schematic diagram illustrating a block circuit of a temperature sensing circuit 110 shown in FIG. 1 according to an embodiment of the disclosure. The temperature sensing circuit 110 shown in FIG. 3 includes multiple temperature switches 111 and a resistor 112. A first terminal of the resistor 112 is configured to receive a first voltage. The first voltage may be set according to design requirements. In the embodiment, the first voltage may be a system voltage Vcc or other positive voltages. A second terminal of the resistor 112 is coupled to the control circuit 120 to provide the voltage value Vout. The temperature switches 111 are connected in series to form a temperature switch string. A first terminal of the temperature switch string is coupled to the second terminal of the resistor 112, and a second terminal of the temperature switch string is configured to receive a second voltage. The second voltage may be set according to design requirements. For example, the second voltage may be a reference voltage GND or other fixed voltages.

The positions of the temperature switches 111 may be determined according to design requirements. For example, in the embodiment, the temperature switches 111 may be disposed corresponding to the heat dissipation holes 101, that is, disposed one-to-one or one-to-many, which is not limited thereto. In some embodiments, the temperature switches 111 may be disposed around at least one heat dissipation hole 101 of the casing 100 of the display device. In some other embodiments, the temperature switches 111 may be disposed around the display element 130 or in the display element 130. In some other embodiments, the temperature switches 111 may be disposed around the control circuit 120.

The temperature switches 111 shown in FIG. 3 may be normal close temperature switches. When the temperature of the display device is in the normal temperature range, all of the temperature switches 111 are turned on, so the voltage value Vout is pulled down to the reference voltage GND. When the temperature of one of the temperature switches 111 reaches the limit temperature (the temperature of the display device exceeds the normal temperature range), the temperature switch 111 is turned off. When any one of the temperature switches 111 is turned off, the resistor 112 may pull up the voltage value Vout to the system voltage Vcc (or to a voltage value close to the system voltage Vcc). The control circuit 120 may determine whether the temperature of the display device exceeds the normal temperature range according to the magnitude of the voltage value Vout. When any one of the temperature switches 111 is turned off, the control circuit 120 may perform the cooling operation, such as shutting down the display element 130 of the display device. In addition, the control circuit 120 may enable an indicator light (not shown) of the display device to flash, so as to inform the user that “the display device is abnormal”.

FIG. 4 is a schematic diagram illustrating the block circuit of the temperature sensing circuit 110 shown in FIG. 1 according to another embodiment of the disclosure. The temperature sensing circuit 110 shown in FIG. 4 includes m resistors 113_1, 113_2, 113_3, . . . , 113_m−1, and 113_m. The temperature sensing circuit 110 shown in FIG. 4 further includes multiple temperature switches 111, an operational amplifier OP1, and a resistor 114. The temperature switches 111 shown in FIG. 4 may be deduced by analogy with reference to the relevant descriptions of the temperature switch 111 shown in FIG. 3, so there will be no reiteration here. In the embodiment shown in FIG. 4, the resistors 113_1 to 113_m are connected in parallel to the temperature switches 111 in the manner of one-to-one.

As shown in FIG. 4, the temperature switches 111 are connected in series to form a temperature switch string. A first terminal of the temperature switch string is coupled to an output terminal of the operational amplifier OP1, and a second terminal of the temperature switch string is coupled to a first input terminal (such as an inverting input terminal) of the operational amplifier OP1 and a first terminal of the resistor 114. The output terminal of the operational amplifier OP1 is also coupled to the control circuit 120 to provide the voltage value Vout. A second input terminal (such as an non-inverting input terminal) of the operational amplifier OP1 is configured to receive a first voltage. The first voltage may be set according to design requirements. For example, the first voltage may be the reference voltage GND or other fixed voltages. A second terminal of the resistor 114 is configured to receive a second voltage. The second voltage may be set according to design requirements. For example, the second voltage may be a system voltage VCC− or other negative voltages.

The resistors 113_1 to 113_m may be set according to design requirements. In some embodiments, the resistance values of the resistors 113_1 to 113_m may be equal to each other. In some other embodiments, the resistance values of the resistors 113_1 to 113_m may not be equal to each other. For example, the resistance values of the resistors 113_1 to 113_m may have a 2ⁿ⁻¹ relationship with each other. According to design requirements, the temperature switches 111 shown in FIG. 4 may be normal close temperature switches or normal open temperature switches.

Here, the implementation example of “the resistance values of the resistors 113_1 to 113_m are equal to each other” and “the temperature switches 111 are normal close temperature switches” is described. It is assumed that the current flowing through the resistor 114 is I, and all of the resistance values of the resistors 113_1 to 113_m are R. When the temperature of the display device is in the normal temperature range, all of the temperature switches 111 are turned on, so the voltage value Vout is the reference voltage GND (or a voltage value close to the reference voltage GND, such as 0V). When one of the temperature switches 111 is turned off (overtemperature occurs), the voltage value Vout is I*R. When three of the temperature switches 111 are turned off (overtemperature occurs), due to the series connection of the resistors, the voltage value Vout is I*(R+R+R)=3*I*R. That is, the level of the voltage value Vout shown in FIG. 4 is related to the number of the turned off temperature switches 111.

The control circuit 120 may know the number of the turned off temperature switches 111 (or the number of turned on switches, that is, the number of overtemperature switches) according to the level of the voltage value Vout. Furthermore, the control circuit 120 may determine a cooling countermeasure according to the number of turned off switches (or the number of turned on switches). For example, the control circuit 120 may determine whether to reduce the brightness of the display element 130 of the display device according to the number of turned off switches (or the number of turned on switches), so as to reduce the brightness of the screen of the display device.

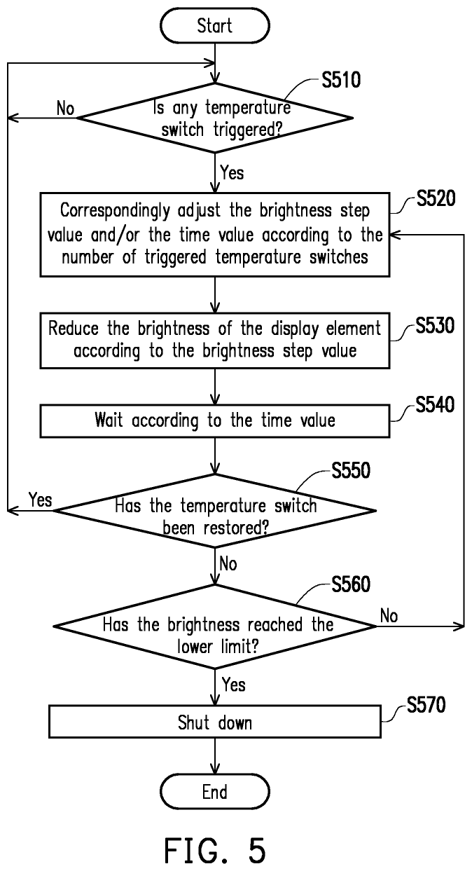

FIG. 5 is a schematic flowchart of a cooling operation (cooling countermeasure) according to an embodiment of the disclosure. Please refer to FIG. 1, FIG. 4, and FIG. 5. In Step S510, the control circuit 120 may determine whether any one of the temperature switches 111 is triggered according to the level of the voltage value Vout. In the case where “the temperature switches 111 are normal close temperature switches”, the control circuit 120 may determine whether any one of the temperature switches 111 is turned off (triggered) according to the level of the voltage value Vout. When one of the temperature switches 111 is turned off (triggered) (the determination result of Step S510 is “Yes”), the control circuit 120 may perform Step S520.

The control circuit 120 may know (determine) the number of the turned off temperature switches 111 (the number of triggered switches) according to the level of the voltage value Vout. In Step S520, the control circuit 120 may correspondingly adjust the brightness step value and/or the time value according to the number of turned off switches (the number of triggered temperature switches). The corresponding relationship between the number of turned off switches (the number of triggered temperature switches) and the brightness step value may be defined according to design requirements, and the corresponding relationship between the number of turned off switches (the number of triggered temperature switches) and the time value may also be defined according to design requirements. For example, the brightness step value may be designed as a preset adjusted value, and the control circuit 120 may shut down 10% or 20% of the brightness of the display element according to the number of turned off switches (the number of triggered temperature switches), and so on, but the disclosure is not limited thereto.

In Step S530, the control circuit 120 may reduce the brightness of the display element 130 of the display device according to the brightness step value. In Step S540, the control circuit 120 may wait according to the time value. When the waiting time has reached the time value, the control circuit 120 may end Step S540 and perform Step S550. In Step S550, the control circuit 120 may again determine the number of the turned off temperature switches 111 (the number of triggered switches) according to the level of the voltage value Vout, thereby determining whether all of the temperature switches 111 are restored (with the temperatures returned to the normal temperature range). In the case where “the temperature switches 111 are normal close temperature switches”, the control circuit 120 may determine in Step S550 whether all of the temperature switches 111 are turned on (restored). When all of the temperature switches 111 are turned on (restored) (the determination result of Step S550 is “Yes”), the control circuit 120 may return to Step S510. When a portion of the temperature switches 111 is still turned off (triggered) (the determination result of Step S550 is “No”), the control circuit 120 may perform Step S560.

In Step S560, the control circuit 120 may check whether the current brightness of the display element 130 has reached the lower limit (minimum brightness). When the current brightness of the display element 130 does not reach the lower limit (the determination result of Step S560 is “No”), the control circuit 120 may return to Step S520. When the current brightness of the display element 130 has reached the lower limit (the determination result of Step S560 is “Yes”), the control circuit 120 may perform Step S570. In Step S570, the control circuit 120 may forcibly shut down the display device.

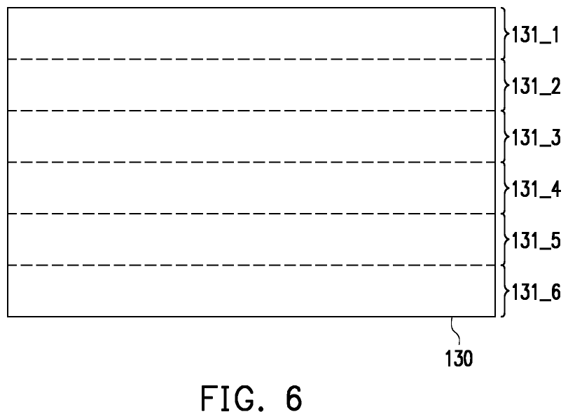

The control circuit 120 may perform another cooling operation (cooling countermeasure) different from the flowchart shown in FIG. 5. For example, the display element 130 of the display device may be divided into multiple display element rows. FIG. 6 is a schematic diagram illustrating the display element 130 being divided into multiple display element rows according to an embodiment of the disclosure. Please refer to FIG. 1 and FIG. 6. The display element 130 of the display device may be divided into multiple display element rows, for example, display element rows 131_1, 131_2, 131_3, 131_4, 131_5, and 131_6 shown in FIG. 6. The number of display element rows of the display element 130 may be set according to design requirements. For example, the number of LEDs included in the display element may be used to distinguish multiple display element rows. The control circuit 120 may know (determine) the number of the turned off temperature switches 111 (or the number of turned on switches, that is, the number of overtemperature switches) according to the level of the voltage value Vout. Furthermore, the control circuit 120 may determine the cooling countermeasure according to the number of the turned off temperature switches 111 (or the number of the turned on temperature switches 111). For example, the control circuit 120 may determine whether to correspondingly shut down at least one of the display element rows 131_1 to 131_6 of the display element 130 according to the number of turned off switches (or the number of turned on switches), so as to shut down the corresponding portion of the screen of the display device.

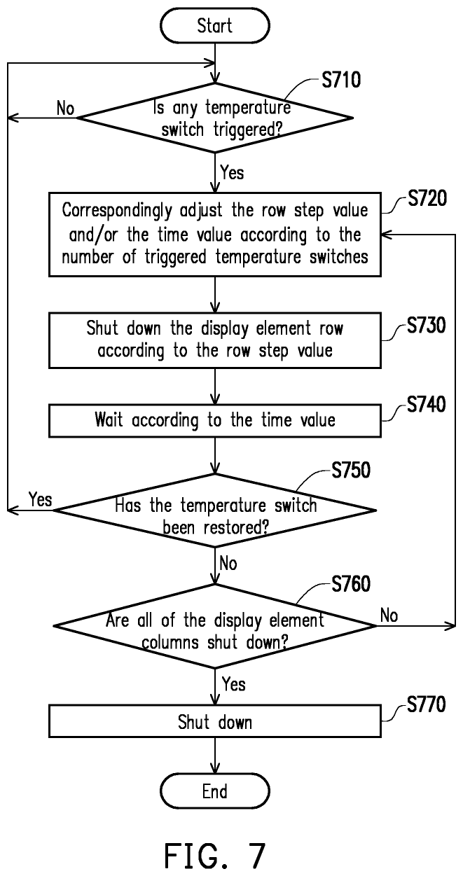

FIG. 7 is a schematic flowchart of a cooling operation (cooling countermeasure) according to another embodiment of the disclosure. Step S710 shown in FIG. 7 may be deduced by analogy with reference to the relevant descriptions of Step S510 shown in FIG. 5, so there will be no reiteration here. Please refer to FIG. 1, FIG. 4, FIG. 6, and FIG. 7. The control circuit 120 may know (determine) the number of the turned off temperature switches 111 (the number of triggered switches) according to the level of the voltage value Vout. In Step S720, the control circuit 120 may correspondingly adjust the row step value and/or the time value according to the number of turned off switches (the number of triggered temperature switches). The corresponding relationship between the number of turned off switches (the number of triggered temperature switches) and the row step value may be defined according to design requirements, and the corresponding relationship between the number of turned off switches (the number of triggered temperature switches) and the time value may also be defined according to design requirements. For example, the row step value may be designed as a preset adjusted value, and the control circuit 120 may shut down 10% or 20% of the number of display elements according to the number of turned off switches (the number of triggered temperature switches), and so on, but the disclosure is not limited thereto.

In Step S730, the control circuit 120 may turn off at least one of the display element rows 131_1 to 131_6 according to the row step value. Steps S740 and S750 shown in FIG. 7 may be deduced by analogy with reference to the relevant descriptions of Steps S540 and S550 shown in FIG. 5, so there will be no reiteration here. When a portion of the temperature switches 111 is still turned off (triggered) (the determination result of Step S750 is “No”), the control circuit 120 may perform Step S760.

In Step S760, the control circuit 120 may check whether all of the display element rows 131_1 to 131_6 of the display element 130 are turned off. When not all of the display element rows 131_1 to 131_6 of the display element 130 are turned off (the determination result of Step S760 is “No”), the control circuit 120 may return to Step S720. When all of the display element rows 131_1 to 131_6 of the display element 130 are turned off (the determination result of Step S760 is “Yes”), the control circuit 120 may perform Step S770. In Step S770, the control circuit 120 may forcibly shut down the display device.

The control circuit 120 may perform another cooling operation (cooling countermeasure) different from the foregoing embodiments. For example, the control circuit 120 may determine the number of the turned off temperature switches 111 (or the number of turned on switches, that is, the number of overtemperature switches) according to the voltage value Vout. The control circuit 120 may determine whether to reduce the brightness of the display element 130 of the display device according to the number of turned off switches (or the number of turned on switches), so as to reduce the brightness of the screen of the display device. The control circuit 120 may also determine whether to correspondingly shut down at least one of the display element rows 131_1 to 131_6 according to the number of turned off switches (or the number of turned on switches), so as to shut down the corresponding portion of the screen of the display device.

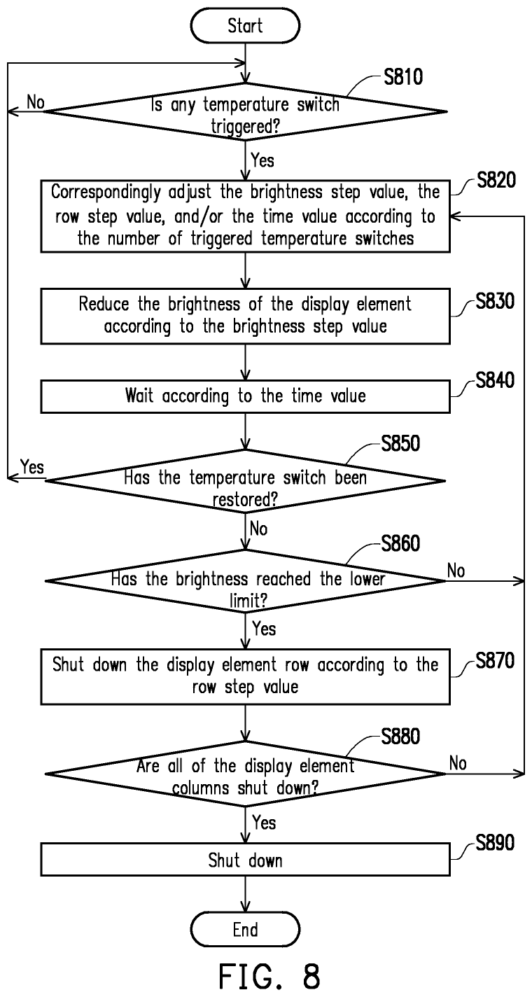

FIG. 8 is a schematic flowchart of a cooling operation (cooling countermeasure) according to yet another embodiment of the disclosure. Step S810 shown in FIG. 8 may be deduced by analogy with reference to the relevant descriptions of Step S510 shown in FIG. 5, so there will be no reiteration here. Please refer to FIG. 1, FIG. 4, FIG. 6, and FIG. 8. The control circuit 120 may know (determine) the number of turned off temperature switches 111 (the number of triggered switches) according to the level of the voltage value Vout. In Step S820, the control circuit 120 may correspondingly adjust the brightness step value, the row step value, and/or the time value according to the number of turned off switches (the number of triggered temperature switches). The corresponding relationship between the number of turned off switches (the number of triggered temperature switches) and the brightness step value may be defined according to design requirements, the corresponding relationship between the number of turned off switches (the number of triggered temperature switches) and the row step value may be defined according to design requirements, and the corresponding relationship between the number of turned off switches (the number of triggered temperature switches) and the time value may also be defined according to design requirements.

Steps S830, S840, S850, and S860 shown in FIG. 8 may be deduced by analogy with reference to the relevant descriptions of Steps S530, S540, S550, and S560 shown in FIG. 5, so there will be no reiteration here. When the current brightness of the display element 130 has reached the lower limit (the determination result of Step S860 is “Yes”), the control circuit 120 may perform Step S870. Steps S870, S880, and S890 shown in FIG. 8 may be deduced by analogy with reference to the relevant descriptions of Steps S730, S760, and S770 shown in FIG. 7, so there will be no reiteration here.

In some other embodiments, the resistance values of the resistors 113_1 to 113_m shown in FIG. 4 may have a 2ⁿ⁻¹ relationship. For example, the resistance value of the resistor 113_1 may be R, the resistance value of the resistor 113_2 may be 2R, and the resistance value of the resistor 113_3 may be 4R. By analogy, the resistance value of the resistor 113_m−1 may be 2^{(m-2)}R, the resistance value of the resistor 113_m may be 2^{(m-1)}R, and the resistance value of the n^{th} resistor is Rₙ=2⁽ⁿ⁻¹⁾R, where n=1, . . . m. According to design requirements, the temperature switches 111 shown in FIG. 4 may be normal close temperature switches or normal open temperature switches.

Here, the implementation example of “the resistance values of the resistors 113_1 to 113_m having a 2ⁿ⁻¹ relationship with each other” and “the temperature switches 111 are normal close temperature switches” is described. It is assumed that the current of the resistor 114 is I, and the resistance values of the resistors 113_1 to 113_m are R. When the temperature of the display device is in the normal temperature range, all of the temperature switches 111 are turned on, so the voltage value Vout is the reference voltage GND (or a voltage value close to the reference voltage GND, such as 0V). When the first one of the temperature switches 111 is turned off (overtemperature occurs), that is, the short circuit between the two terminals of the resistor 113_1 is released, the voltage value Vout is I*R. When the first, second, and m^{th} temperature switches 111 are turned off (overtemperature occurs), that is, the short circuit between the two terminals of the resistors 113_1, 113_2, and 113_m is released, the voltage value Vout is I*(R+2R+2^{m}R)=(2⁰±2¹+2th)*I*R. That is, the level of the voltage value Vout shown in FIG. 4 is related to the positions where the temperature switches 111 are turned off and/or the number of turned off switches.

In the case where “the resistance values of the resistors 113_1 to 113_m have a 2ⁿ⁻¹ relationship with each other”, the control circuit 120 shown in FIG. 4 may know the number of the turned off temperature switches 111 according to the level of the voltage value Vout (or the number of turned on switches, that is, the number of overtemperature switches). Furthermore, the control circuit 120 may determine a cooling countermeasure according to the number of turned off switches (or the number of turned on switches). For example, the control circuit 120 may determine whether to reduce the brightness of the display element 130 of the display device according to the number of turned off switches (or the number of turned on switches), so as to reduce the brightness of the screen of the display device. The implementation example of this paragraph may also apply the cooling operation (cooling countermeasure) shown in FIG. 5.

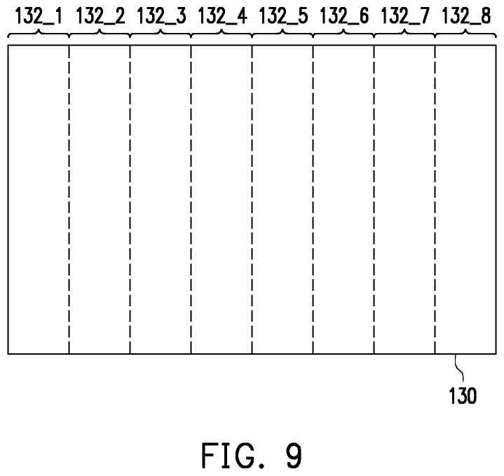

The control circuit 120 shown in FIG. 4 may perform another cooling operation (cooling countermeasure) different from the foregoing embodiments. For example, the display element 130 of the display device may be divided into multiple display element columns. FIG. 9 is a schematic diagram illustrating a display element 130 being divided into multiple display element columns according to an embodiment of the disclosure. Please refer to FIG. 1 and FIG. 9. The display element 130 of the display device may be divided into multiple display element columns, for example, display element columns 132_1, 132_2, 132_3, 132_4, 132_5, 132_6, 132_7, and 132_8 shown in FIG. 9. The number of display element columns of the display element 130 may be set according to design requirements. In the case where “the resistance values of the resistors 113_1 to 113_m have a 2ⁿ⁻¹ relationship with each other”, the control circuit 120 may know (determine) the positions where the temperature switches 111 are turned off (or turned on) according to the level of the voltage value Vout. Furthermore, the control circuit 120 may determine a cooling countermeasure according to the position. For example, the control circuit 120 may determine whether to correspondingly shut down at least one corresponding display element column of the display element columns 132_1 to 132_8 of the display element 130 according to the position, so as to shut down the corresponding portion of the screen of the display device.

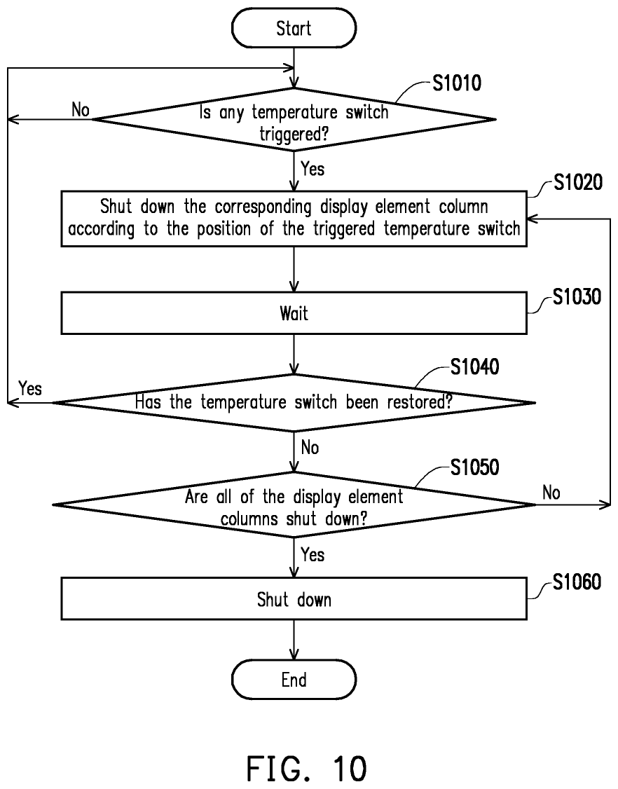

FIG. 10 is a schematic flowchart of a cooling operation (cooling countermeasure) according to yet another embodiment of the disclosure. Step S1010 shown in FIG. 10 may be deduced by analogy with reference to the relevant descriptions of Step S510 shown in FIG. 5, so there will be no reiteration here. Please refer to FIG. 1, FIG. 4, FIG. 9, and FIG. 10. In the case where “the resistance values of the resistors 113_1 to 113_m have a 2ⁿ⁻¹ relationship with each other”, the control circuit 120 may determine the position where a number of the temperature switches 111 is turned off (triggered) according to the level of the voltage value Vout. In Step S1020, the control circuit 120 may determine whether to correspondingly shut down at least one of the display element columns 132_1 to 132_8 of the display element 130 according to the position, so as to shut down the corresponding portion of the screen of the display device.

In Step S1030, the control circuit 120 may wait. When the waiting time has reached a preset length of time, the control circuit 120 may end Step S1030 and perform Step S1040. In Step S1040, the control circuit 120 may again determine whether the temperature switches 111 are turned off (triggered) according to the level of the voltage value Vout, thereby determining whether all of the temperature switches 111 are restored (with the temperatures returned to the normal temperature range). In the case where “the temperature switches 111 are normal close temperature switches”, the control circuit 120 may determine in Step S1040 whether all of the temperature switches 111 are turned on (restored). When all of the temperature switches 111 are turned on (restored) (the determination result of Step S1040 is “Yes”), the control circuit 120 may return to Step S1010. When some of the temperature switches 111 are still turned off (triggered) (the determination result of Step S1040 is “No”), the control circuit 120 may perform Step S1050.

In Step S1050, the control circuit 120 may check whether all of the display element columns 132_1 to 132_8 of the display element 130 are turned off. When not all of the display element columns 132_1 to 132_8 of the display element 130 are turned off (the determination result of Step S1050 is “No”), the control circuit 120 may return to Step S1020. When all of the display element columns 132_1 to 132_8 of the display element 130 are turned off (the determination result of Step S1050 is “Yes”), the control circuit 120 may perform Step S1060. In Step S1060, the control circuit 120 may forcibly shut down the display device.

The control circuit 120 shown in FIG. 4 may perform another cooling operation (cooling countermeasure) different from the foregoing embodiments. For example, the control circuit 120 may determine the position where a number of the temperature switch 111 is turned off (or turned on), and the number of the turned off temperature switches 111 (or the number of turned on switches) according to the voltage value Vout. The control circuit 120 may determine whether to correspondingly reduce the brightness of the display element 130 of the display device according to the number of turned off switches (or the number of turned on switches), so as to reduce the brightness of the screen of the display device. The control circuit 120 may also correspondingly shut down at least one corresponding display element column of the display element columns 132_1 to 132_8 according to the position, so as to shut down the corresponding portion of the screen of the display device.

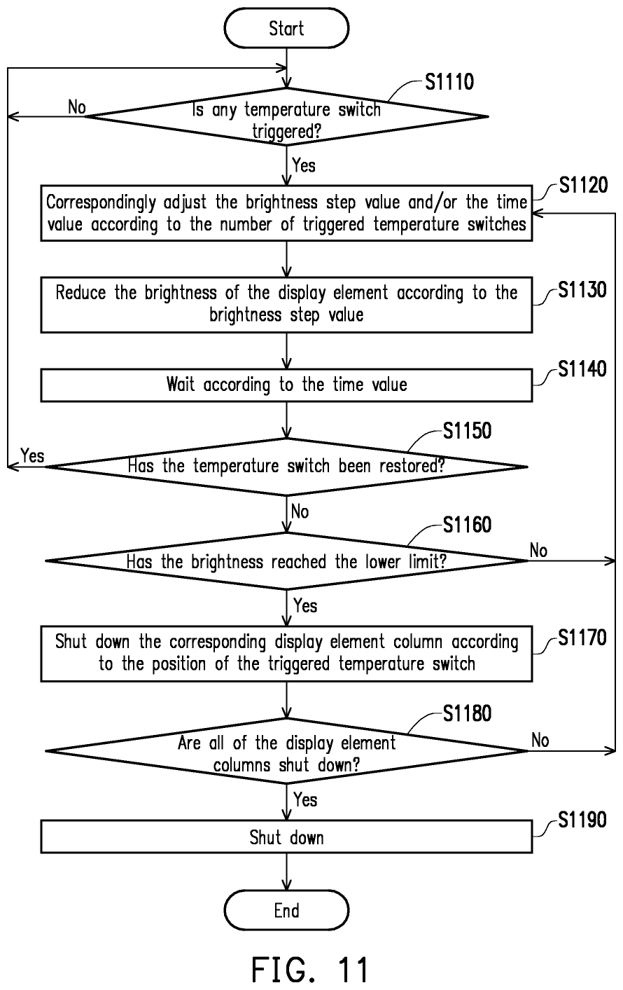

FIG. 11 is a schematic flowchart of a cooling operation (cooling countermeasure) according to another embodiment of the disclosure. Step S1110 shown in FIG. 11 may be analogized with reference to the relevant descriptions of Step S510 shown in FIG. 5, so there will be no reiteration here. Please refer to FIG. 1, FIG. 4, FIG. 9, and FIG. 11. The control circuit 120 may know (determine) the number and the position of the turned off temperature switches 111 (the number of triggered switches) according to the level of the voltage value Vout.

In Step S1120, the control circuit 120 may correspondingly adjust the brightness step value and/or the time value according to the number of turned off switches (the number of triggered temperature switches). The corresponding relationship between the number of turned off switches (the number of triggered temperature switches) and the brightness step value may be defined according to design requirements, and the corresponding relationship between the number of turned off switches (the number of triggered temperature switches) and the time value may also be defined according to design requirements.

Steps S1130, S1140, S1150, and S1160 shown in FIG. 11 may be deduced by analogy with reference to the relevant descriptions of Steps S530, S540, S550, and S560 shown in FIG. 5, so there will be no reiteration here. When the current brightness of the display element 130 has reached the lower limit (the determination result of Step S1160 is “Yes”), the control circuit 120 may perform Step S1170. Steps S1170, S1180, and S1190 shown in FIG. 11 may be deduced by analogy with reference to the relevant descriptions of Steps S1020, S1050, and S1060 shown in FIG. 10, so there will be no reiteration here.

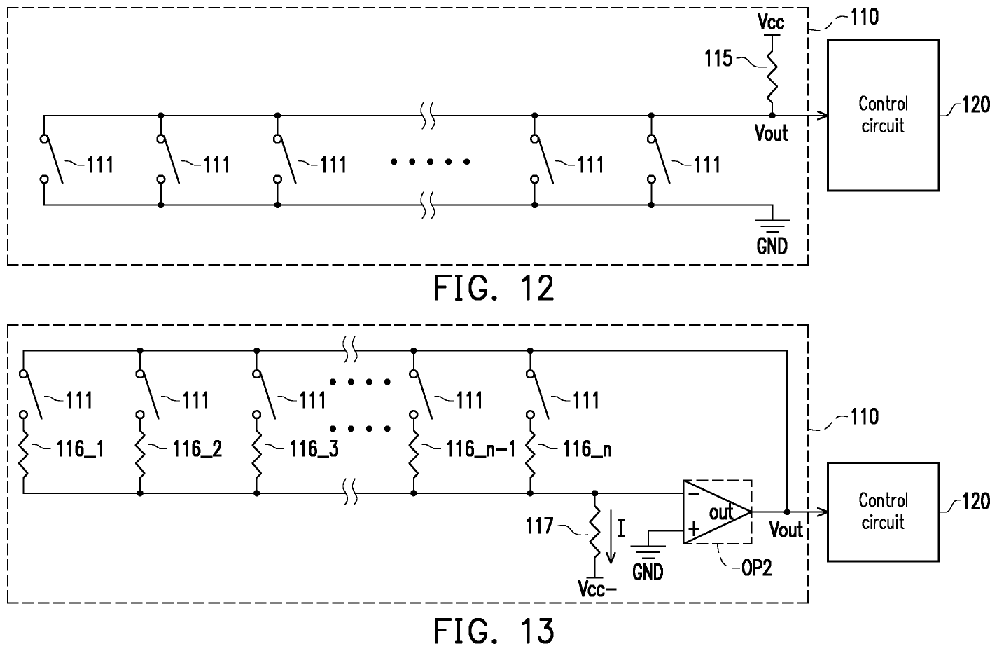

FIG. 12 is a schematic diagram illustrating the block circuit of the temperature sensing circuit 110 shown in FIG. 1 according to yet another embodiment of the disclosure. The temperature sensing circuit 110 shown in FIG. 12 includes multiple temperature switches 111 and a resistor 115. A first terminal of the resistor 115 is configured to receive a first voltage. The first voltage may be set according to design requirements. For example, the first voltage may be the system voltage Vcc or other positive voltages. A second terminal of the resistor 115 is coupled to the control circuit 120 to provide the voltage value Vout. A first terminal of each of the temperature switches 111 is coupled to the second terminal of the resistor 115. A second terminal of each of the temperature switches 111 is configured to receive a second voltage. The second voltage may be set according to design requirements. For example, the second voltage may be the reference voltage GND or other fixed voltages.

The positions of the temperature switches 111 may be determined according to design requirements. For example, in some embodiments, the temperature switches 111 may be disposed around at least one heat dissipation hole 101 of the casing 100 of the display device. In some other embodiments, the temperature switches 111 may be disposed around the display element 130 or in the display element 130. In some other embodiments, the temperature switches 111 may be disposed around the control circuit 120.

The temperature switches 111 shown in FIG. 12 may be normal open temperature switches. When the temperature of the display device is in the normal temperature range, all of the temperature switches 111 are turned off, so the resistor 115 may pull up the voltage value Vout to the system voltage Vcc (or to a voltage value close to the system voltage Vcc). When the temperature of one of the temperature switches 111 reaches the limit temperature (the temperature of the display device exceeds the normal temperature range), the temperature switch 111 is turned on. When any one of the temperature switches 111 is turned on, the voltage value Vout is pulled down to the reference voltage GND. The control circuit 120 may determine whether the temperature of the display device exceeds the normal temperature range according to the voltage value Vout. When any one of the temperature switches 111 is turned on, the control circuit 120 may perform a cooling operation, such as shutting down the display element 130 of the display device. In addition, the control circuit 120 may enable the indicator light (not shown) of the display device to flash, so as to inform the user that “the display device is abnormal”.

FIG. 13 is a schematic diagram illustrating the block circuit of the temperature sensing circuit 110 shown in FIG. 1 according to another embodiment of the disclosure. The temperature sensing circuit 110 shown in FIG. 13 includes n resistors 116_1, 116_2, 116_3, . . . , 116_n−1, and 116_n. The temperature sensing circuit 110 shown in FIG. 13 further includes multiple temperature switches 111, an operational amplifier OP2, and a resistor 117. The temperature switches 111 shown in FIG. 13 may be deduced by analogy with reference to the relevant descriptions of the temperature switches 111 shown in FIG. 12, so there will be no reiteration here. In the embodiment shown in FIG. 13, first terminals of the resistors 116_1 to 116_n are coupled to first terminals of the temperature switches 111 in the manner of one-to-one. An output terminal of the operational amplifier OP2 is coupled to the control circuit 120 to provide the voltage value Vout. The output terminal of the operational amplifier OP2 is also coupled to second terminals of the temperature switches 111. A first input terminal (such as an inverting input terminal) of the operational amplifier OP2 is coupled to second terminals of the resistors 116_1 to 116_n. A second input terminal (such as a non-inverting input terminal) of the operational amplifier OP2 is configured to receive a first voltage. The first voltage may be set according to design requirements. For example, the first voltage may be the reference voltage GND or other fixed voltages. A first terminal of the resistor 117 is coupled to the second terminals of the resistors 116_1 to 116_n. A second terminal of the resistor 117 is configured to receive a second voltage. The second voltage may be set according to design requirements. For example, the second voltage may be the system voltage VCC− or other negative voltages.

The resistors 116_1 to 116_n may be set according to design requirements. In some embodiments, the resistance values of the resistors 116_1 to 116_n may be equal to each other. In some other embodiments, the resistance values of the resistors 116_1 to 116_n may not be equal to each other. For example, the resistance values of the resistors 116_1 to 116_n may have a 2ⁿ⁻¹ relationship with each other. According to design requirements, the temperature switches 111 shown in FIG. 13 may be normal close temperature switches or normal open temperature switches.

Here, the implementation example of “the resistance values of the resistors 116_1 to 116_n are equal to each other” and “the temperature switches 111 are normal close temperature switches” is described. It is assumed that the current of the resistor 114 is I, and all of the resistance values of the resistors 116_1 to 116_n are R. When the temperature of the display device is in the normal temperature range, all of the temperature switches 111 are turned on, so the voltage value Vout is I*R/n, where n is the number of the resistors 116_1 to 116_n.

Here, the implementation example of “the resistance values of the resistors 116_1 to 116_n are equal to each other” and “the temperature switches 111 are normal open temperature switches” is described. When one of the temperature switches 111 is turned on (overtemperature occurs), the voltage value Vout is I*R. When three of the temperature switches 111 are turned on (overtemperature occurs), due to the parallel connection of the resistors, the voltage value Vout is I*R/3. That is, the level of the voltage value Vout shown in FIG. 13 is related to the number of the turned off temperature switches 111 (or the number of turned on switches).

The control circuit 120 may know the number of the turned off temperature switches 111 (or the number of turned on switches, that is, the number of overtemperature switches) according to the level of the voltage value Vout. Furthermore, the control circuit 120 may determine a cooling countermeasure according to the number of turned off switches (or the number of turned on switches). For example, the control circuit 120 may determine whether to reduce the brightness of the display element 130 of the display device according to the number of turned off switches (or the number of turned on switches), so as to reduce the brightness of the screen of the display device. That is, the embodiment shown in FIG. 13 may also apply the cooling operation (cooling countermeasure) of FIG. 5.

The control circuit 120 shown in FIG. 13 may perform another cooling operation (cooling countermeasure) different from the flowchart shown in FIG. 5. For example, the display element 130 of the display device may be divided into multiple display element rows, as shown in FIG. 6. The control circuit 120 may know (determine) the number of the turned off temperature switches 111 (or the number of turned on switches, that is, the number of overtemperature switches) according to the level of the voltage value Vout. Furthermore, the control circuit 120 may determine a cooling countermeasure according to the number of turned off switches (or the number of turned on switches). For example, the control circuit 120 may determine whether to correspondingly shut down at least one of the display element rows 131_1 to 131_6 of the display element 130 according to the number of turned off switches (or the number of turned on switches), so as to shut down the corresponding portion of the screen of the display device. That is, the embodiment shown in FIG. 13 may also apply the cooling operation (cooling countermeasure) of FIG. 7.

The control circuit 120 shown in FIG. 13 may perform another cooling operation (cooling countermeasure) different from the foregoing embodiments. For example, the control circuit 120 may determine the number of the turned off temperature switches 111 (or the number of turned on switches, that is, the number of overtemperature switches) according to the voltage value Vout. The control circuit 120 may determine whether to reduce the brightness of the display element 130 of the display device according to the number of turned off switches (or the number of turned on switches), so as to reduce the brightness of the screen of the display device. The control circuit 120 may also determine whether to correspondingly shut down at least one of the display element rows 131_1 to 131_6 according to the number of turned off switches (or the number of turned on switches), so as to shut down the corresponding portion of the screen of the display device. That is, the embodiment shown in FIG. 13 may also apply the cooling operation (cooling countermeasure) of FIG. 8.

In some other embodiments, the resistance values of the resistors 116_1 to 116_n shown in FIG. 13 may have a 2ⁿ⁻¹ relationship. For example, the resistance value of the resistor 116_1 may be R, the resistance value of the resistor 116_2 may be 2R, and the resistance value of the resistor 116_3 may be 4R. By analogy, the resistance value of the resistor 116_n−1 may be 2⁽ⁿ⁻²⁾R, and the resistance value of the resistor 116_n may be 2⁽ⁿ⁻¹⁾R. According to design requirements, the temperature switches 111 shown in FIG. 13 may be normal close temperature switches or normal open temperature switches.

Here, the implementation example of “the resistance values of the resistors 116_1 to 116_n have a 2ⁿ⁻¹ relationship with each other” and “the temperature switches 111 are normal close temperature switches” is described. It is assumed that the current of the resistor 114 is I, and the resistance values of the resistors 116_1 to 116_n are R. When the temperature of the display device is in the normal temperature range, all of the temperature switches 111 are turned on, so the voltage value Vout is I*R/[(½⁰)+(½¹)±(½²)+ . . . +(½ⁿ)].

Here, the implementation example of “the resistance values of the resistors 116_1 to 116_n have a 2ⁿ⁻¹ relationship with each other” and “the temperature switches 111 are normal open temperature switches” is described. When the second one of the temperature switches 111 is turned on (overtemperature occurs), that is, the two terminals of the resistor 116_2 are respectively coupled to the first input terminal and the output terminal of the operational amplifier OP2, the voltage value Vout is I*R/[(½¹)]=I*2R. When the first, third, and n^{th} temperature switches 111 are turned on (overtemperature occurs), that is, the two terminals of the resistors 116_1, 116_3, and 116_n are respectively coupled to the first input terminal and the output terminal of the operational amplifier OP2, the voltage value Vout is) I*R/[(½⁰)+(½²)+(½ⁿ)]. That is, the level of the voltage value Vout shown in FIG. 13 is related to the positions where the temperature switches 111 are turned off (or turned on), and/or the level of the voltage value Vout is related to the number of the turned off temperature switches 111 (or the number of turned on switches).

In the case where “the resistance values of the resistors 116_1 to 116_n have a 2ⁿ⁻¹ relationship with each other”, the control circuit 120 shown in FIG. 13 may know the number of the turned off temperature switches 111 (or the number of turned on switches, that is, the number of overtemperature switches) according to the level of the voltage value Vout. Furthermore, the control circuit 120 may determine a cooling countermeasure according to the number of turned off switches (or the number of turned on switches). For example, the control circuit 120 may determine whether to reduce the brightness of the display element 130 of the display device according to the number of turned off switches (or the number of turned on switches), so as to reduce the brightness of the screen of the display device. The implementation example may also apply the cooling operation (cooling countermeasures) shown in FIG. 5.

The control circuit 120 shown in FIG. 13 may perform another cooling operation (cooling countermeasure) different from the foregoing embodiments. For example, the display element 130 of the display device may be divided into multiple display element columns, as shown in FIG. 9. In the case where “the resistance values of the resistors 116_1 to 116_n have a 2ⁿ¹ relationship with each other”, the control circuit 120 may know (determine) the positions where the temperature switches 111 are turned off (or turned on) according to the level of the voltage value Vout. Furthermore, the control circuit 120 may determine a cooling countermeasure according to the position. For example, the control circuit 120 may determine whether to correspondingly shut down at least one corresponding display element column of the display element columns 132_1 to 132_8 of the display element 130 according to the position, so as to shut down the corresponding portion of the screen of the display device. That is, the embodiment shown in FIG. 13 may also apply the cooling operation (cooling countermeasure) of FIG. 10.

The control circuit 120 shown in FIG. 13 may perform another cooling operation (cooling countermeasure) different from the foregoing embodiments. For example, the control circuit 120 may determine the position where a number of the temperature switch 111 is turned off (or turned on), and the number of the turned off temperature switch 111 (or the number of turned on switches) according to the voltage value Vout. The control circuit 120 may determine whether to correspondingly reduce the brightness of the display element 130 of the display device according to the number of turned off switches (or the number of turned on switches), so as to reduce the brightness of the screen of the display device. The control circuit 120 may also correspondingly shut down at least one corresponding display element column of the display element columns 132_1 to 132_8 according to the position, so as to shut down the corresponding portion of the screen of the display device. That is, the embodiment shown in FIG. 13 can also apply the cooling operation (cooling countermeasure) of FIG. 11.

According to different design requirements, the implementation of the block of the control circuit 120 may be hardware, firmware, software (i.e. program), or a combination of multiple of the three forms.

In terms of the hardware form, the block of the control circuit 120 may be implemented in a logic circuit on an integrated circuit. The relevant functions of the control circuit 120 may be implemented as hardware using hardware description languages (such as Verilog HDL or VHDL) or other suitable programming languages. For example, the relevant functions of the control circuit 120 may be implemented in one or more controllers, microcontrollers, microprocessors, application-specific integrated circuits (ASICs), digital signal processors (DSPs), field programmable gate arrays (FPGAs), and/or various logic blocks, modules, and circuits in other processing units.

In terms of the software form and/or firmware forms, the relevant functions of the control circuit 120 may be implemented as programming codes. For example, conventional programming languages (such as C, C++, or assembly language) or other suitable programming languages are used to implement the control circuit 120. The programming codes may be recorded/stored in a recording medium. The recording medium includes, for example, a read only memory (ROM), a storage device, and/or a random access memory (RAM). A computer, a central processing unit (CPU), a controller, a microcontroller, or a microprocessor may read and execute the programming codes from the recording medium to achieve relevant functions. A “non-transitory computer readable medium”, such as a tape, a disk, a card, a semiconductor memory, a programmable designed logic circuit, etc. may be used as the recording medium. Furthermore, the program may also be provided to the computer (or CPU) via any transmission medium (communication network, broadcast wave, etc.). The communication network is, for example, the Internet, wired communication, wireless communication, or other communication media.

In summary, the display device and the temperature protection method according to the foregoing embodiments may include the temperature sensing circuit 110 disposed in the casing 100 of the display device. The control circuit 120 may determine whether to perform at least one cooling operation according to the operation of the temperature sensing circuit 110. The cooling operation may reduce the temperature of the display device to prevent the temperature of the display device from being too high.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A display device, comprising a temperature sensing circuit and a control circuit, wherein
the temperature sensing circuit is disposed in a casing of the display device and is configured to change a resistance value according to a temperature of the display device, so as to generate a voltage value; and
the control circuit is configured to determine whether to perform at least one cooling operation according to the voltage value of the temperature sensing circuit, so as to reduce the temperature of the display device.

2. The display device according to claim 1, wherein the temperature sensing circuit is disposed around at least one heat dissipation hole of the casing.

3. The display device according to claim 2, wherein the at least one cooling operation comprises shutting down a display element of the display device, reducing a brightness of a screen of the display device, and shutting down a corresponding portion of the screen of the display device.

4. The display device according to claim 3, wherein the temperature sensing circuit comprises a plurality of temperature switches configured to be selectively turned on or turned off according to the temperature, so as to change the resistance value.

5. The display device according to claim 4, wherein the temperature sensing circuit further comprises a resistor, wherein
the resistor has a first terminal and a second terminal, wherein the first terminal is configured to receive a first voltage, the second terminal is coupled to the control circuit, the plurality of temperature switches are connected in series to form a temperature switch string, a first terminal of the temperature switch string is coupled to the second terminal of the resistor, and a second terminal of the temperature switch string is configured to receive a second voltage.

6. The display device according to claim 4, wherein when any one of the plurality of temperature switches is turned off, the control circuit shuts down the display element of the display device.

7. The display device according to claim 4, wherein the temperature sensing circuit further comprises a plurality of first resistors, an operational amplifier, and a second resistor, wherein
each of the plurality of first resistors is connected in parallel to each of the plurality of temperature switches in a manner of one-to-one, and the plurality of temperature switches are connected in series with each other to form a temperature switch string;
the operational amplifier has an output terminal coupled to a first terminal of the temperature switch string and the control circuit, wherein a first input terminal of the operational amplifier is coupled to a second terminal of the temperature switch string, and a second input terminal of the operational amplifier is configured to receive a first voltage; and
the second resistor has a first terminal coupled to the second terminal of the temperature switch string, wherein a second terminal of the second resistor is configured to receive a second voltage.

8. The display device according to claim 7, wherein resistance values of the plurality of first resistors are equal to each other.

9. The display device according to claim 4, wherein
the control circuit determines a number of turned off switches of the plurality of temperature switches according to the voltage value; and
the control circuit determines whether to reduce a brightness of the display element of the display device according to the number of turned off switches, so as to reduce the brightness of the screen of the display device.

10. The display device according to claim 9, wherein when the control circuit reduces the brightness of the display element of the display device, a brightness step value is adjusted according to the number of turned off switches; and
the brightness of the display element of the display device is reduced according to the brightness step value.

11. The display device according to claim 4, wherein
the display element of the display device is divided into a plurality of display element rows;
the control circuit determines a number of turned off switches of the plurality of temperature switches according to the voltage value; and
the control circuit determines whether to correspondingly shut down at least one of the plurality of display element rows according to the number of turned off switches, so as to shut down the corresponding portion of the screen of the display device.

12. The display device according to claim 11, wherein when the control circuit shuts down at least one of the plurality of display element rows, a row step value is correspondingly adjusted according to the number of turned off switches; and
at least one of the plurality of display element rows is shut down according to the row step value.

13. The display device according to claim 4, wherein
the control circuit determines a number of turned off switches of the plurality of temperature switches according to the voltage value;
the control circuit determines whether to reduce a brightness of the display element of the display device according to the number of turned off switches, so as to reduce the brightness of the screen of the display device; and
the control circuit determines whether to correspondingly shut down at least one of the plurality of display element rows according to the turned off switches, so as to shut down the corresponding portion of the screen of the display device.

14. The display device according to claim 4, wherein
the display element of the display device is divided into a plurality of display element columns;
the control circuit determines a position where a number of the plurality of temperature switches is turned off according to the voltage value; and
the control circuit correspondingly shuts down at least one corresponding display element column of the plurality of display element columns according to the position, so as to shut down the corresponding portion of the screen of the display device.

15. The display device according to claim 4, wherein
the display element of the display device is divided into a plurality of display element columns;
the control circuit determines a number and a position of turned off switches of the plurality of temperature switches according to the voltage value;
the control circuit determines whether to correspondingly reduce a brightness of the display element of the display device according to the number of turned off switches, so as to reduce the brightness of the screen of the display device; and
the control circuit correspondingly shuts down at least one corresponding display element column of the plurality of display element columns according to the position, so as to shut down the corresponding portion of the screen of the display device.

16. The display device according to claim 4, wherein the temperature sensing circuit further comprises a resistor, wherein
the resistor has a first terminal and a second terminal, wherein the first terminal is configured to receive a first voltage, the second terminal is coupled to the control circuit, a first terminal of each of the plurality of temperature switches is coupled to the second terminal of the resistor, and a second terminal of each of the plurality of temperature switches is coupled to a second voltage.

17. The display device according to claim 4, wherein when any one of the plurality of temperature switches is turned on, the control circuit shuts down the display element of the display device.

18. The display device according to claim 4, wherein the temperature sensing circuit further comprises a plurality of first resistors, an operational amplifier, and a second resistor, wherein
a first terminal of each of the plurality of first resistors is coupled to a first terminal of each of the plurality of temperature switches in a manner of one-to-one;
the operational amplifier has an output terminal coupled to the control circuit and a second terminal of each of the plurality of temperature switches, wherein a first input terminal of the operational amplifier is coupled to a second terminal of each of the plurality of first resistors, and a second input terminal of the operational amplifier is configured to receive a first voltage; and
the second resistor has a first terminal coupled to the second terminal of each of the plurality of first resistors, wherein a second terminal of the second resistor is configured to receive a second voltage.

19. The display device according to claim 18, wherein resistance values of the plurality of first resistors are equal to each other.

20. A temperature protection method of a display device, comprising:
changing a resistance value according to a temperature of the display device through a temperature sensing circuit to generate a voltage value; and
determining whether to perform at least one cooling operation according to the voltage value of the temperature sensing circuit through a control circuit, so as to reduce the temperature of the display device.

21. The temperature protection method according to claim 20, wherein the temperature sensing circuit is disposed around at least one heat dissipation hole of a casing.

22. The temperature protection method according to claim 21, wherein the at least one cooling operation comprises shutting down a display element of the display device, reducing a brightness of a screen of the display device, and shutting down a corresponding portion of the screen of the display device.

23. The temperature protection method according to claim 22, wherein the temperature sensing circuit comprises a plurality of temperature switches configured to be selectively turned on or turned off according to the temperature, so as to change the resistance value.

24. The temperature protection method according to claim 23, further comprising:
shutting down the display element of the display device by the control circuit when any one of the plurality of temperature switches is turned off.

25. The temperature protection method according to claim 23, further comprising:
determining a number of turned off switches of the plurality of temperature switches according to the voltage value by the control circuit; and
determining whether to reduce a brightness of the display element of the display device according to the number of turned off switches by the control circuit, so as to reduce the brightness of the screen of the display device.

26. The temperature protection method according to claim 25, wherein when the control circuit reduces the brightness of the display element of the display device, a brightness step value is adjusted according to the number of turned off switches; and
the brightness of the display element of the display device is reduced according to the brightness step value.

27. The temperature protection method according to claim 23, further comprising:
dividing the display element of the display device into a plurality of display element rows;
determining a number of turned off switches of the plurality of temperature switches according to the voltage value by the control circuit; and
determining whether to correspondingly shut down at least one of the plurality of display element rows according to the number of turned off switches by the control circuit, so as to shut down the corresponding portion of the screen of the display device.

28. The temperature protection method according to claim 27, wherein when the control circuit shuts down at least one of the plurality of display element rows, a row step value is correspondingly adjusted according to the number of turned off switches; and
at least one of the plurality of display element rows is shut down according to the row step value.

29. The temperature protection method according to claim 23, further comprising:
determining a number of turned off switches of the plurality of temperature switches according to the voltage value by the control circuit;
determining whether to reduce a brightness of the display element of the display device according to the number of turned off switches by the control circuit, so as to reduce the brightness of the screen of the display device; and
determining whether to correspondingly shut down at least one of the plurality of display element rows according to the number of turned off switches by the control circuit, so as to shut down the corresponding portion of the screen of the display device.

30. The temperature protection method according to claim 23, further comprising:
dividing the display element of the display device into a plurality of display element columns;
determining a position where a number of the plurality of temperature switches is turned off according to the voltage value by the control circuit; and
correspondingly shutting down at least one corresponding display element column of the plurality of display element columns according to the position by the control circuit, so as to shut down the corresponding portion of the screen of the display device.

31. The temperature protection method according to claim 23, further comprising:
dividing the display element of the display device into a plurality of display element columns;
determining a number and a position of a number of turned off switches of the temperature switches according to the voltage value by the control circuit;
determining whether to correspondingly reduce a brightness of the display element of the display device according to the number of turned off switches by the control circuit, so as to reduce the brightness of the screen of the display device; and
correspondingly shutting down at least one corresponding display element column of the plurality of display element columns according to the position by the control circuit, so as to shut down the corresponding portion of the screen of the display device.

32. The temperature protection method according to claim 23, further comprising:
shutting down the display element of the display device by the control circuit when any one of the plurality of temperature switches is turned on.
